(19) United States
(12) Patent Application Publication
(10) Pub. No.: US 2025/0034710 A1
(43) Pub. Date: Jan. 30, 2025

(54) SUBSTRATE PROCESSING APPARATUS

(71) Applicant: JUSUNG ENGINEERING CO., LTD., Gwangju-si, Gyeonggi-do (KR)

(72) Inventors: Jun Young KIM, Gwangju-si, Gyeonggi-do (KR); Sang Yun CHA, Gwangju-si, Gyeonggi-do (KR); Ji Hun LEE, Gwangju-si, Gyeonggi-do (KR); Dae Soo JANG, Gwangju-si, Gyeonggi-do (KR)

(21) Appl. No.: 18/687,294

(22) PCT Filed: Sep. 2, 2022
(86) PCT No.: PCT/KR2022/013189

§ 371 Date: Feb. 27, 2024

(30) Foreign Application Priority Data
Sep. 9, 2021 (KR) 10-2021-0120180

(51) Int. Cl. C23C 16/455; C23C 16/509

(52) U.S. Cl. CPC C23C 16/45563; C23C 16/509

(57) ABSTRACT

The present inventive concept relates to a substrate processing apparatus comprising: a chamber; a substrate support part which supports at least one substrate in the chamber; a lower plate which is disposed above the substrate support part; and an upper plate which is disposed above the lower plate, wherein: the upper plate includes a first spray hole which provides a first gas and a second spray hole which provides a second gas; and the lower plate includes a first opening which is disposed under the first spray hole so as to allow the first gas provided from the first spray hole to pass therethrough and a second opening which is disposed under the second spray hole so as to allow the second gas provided from the second spray hole to pass therethrough.

### TECHNICAL FIELD

The present inventive concept relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process is performed on a substrate by a substrate processing apparatus.

A substrate processing apparatus of the related art includes a substrate supporting unit which supports a substrate and a gas injection unit which injects toward the substrate supporting unit. The gas injection unit includes a plurality of openings for injecting a gas. The gas passes through the openings and is injected toward different portions of the substrate supporting unit.

Here, the substrate processing apparatus of the related art is implemented so that a first gas and a second gas pass through each of the openings and are injected toward the substrate supporting unit. That is, the first gas and the second gas are mixed in each of the openings. Therefore, the substrate processing apparatus of the related art has a problem where particles occur like being deposited on the gas injection unit as the first gas and the second gas react.

### DISCLOSURE

### Technical Problem

The present inventive concept is devised to solve the above-described problem and is for providing a substrate processing apparatus which may decrease the amount of particles occurring in a process of injecting a first gas and a second gas onto a substrate supporting unit.

### Technical Solution

To accomplish the above-described objects, the present inventive concept may include the following elements.

A substrate processing apparatus according to the present inventive concept may include: a chamber; a substrate supporting unit supporting at least one substrate in the chamber; a lower plate disposed over the substrate supporting unit; and an upper plate disposed over the lower plate. The upper plate may include a first injection hole providing a first gas and a second injection hole providing a second gas. The lower plate may include a first opening disposed under the first injection hole to allow the first gas provided from the first injection hole to pass through the first opening, and a second opening disposed under the second injection hole to allow the second gas provided from the second injection hole to pass through the second opening.

### Advantageous Effect

According to the present inventive concept, the following effects may be realized.

The present inventive concept is implemented so that a first gas flows through a first injection hole and a first opening and a second gas flows through a second injection hole and a second opening. Therefore, the present inventive concept may decrease the mixed amount of the first gas and the second gas before the first gas and the second gas are injected onto a substrate supporting unit, and thus, may reduce particles which occur as the first gas and the second gas react before the first gas and the second gas are injected onto the substrate supporting unit. Accordingly, the present inventive concept may enhance the quality of a substrate on which a processing process is completed, and moreover, may increase a period of a cleaning operation which should be performed for removing particles, thereby contributing to reduce the process cost.

### DESCRIPTION OF DRAWINGS

FIG. 1 is a schematic block diagram of a substrate processing apparatus according to the present inventive concept.

FIG. 2 is a schematic side cross-sectional view of a lower plate and an upper plate in the substrate processing apparatus according to the present inventive concept.

FIG. 3 is an enlarged view illustrating the enlargement of a portion A of FIG. 2.

FIG. 4 is a schematic bottom cross-sectional view of a lower plate in the substrate processing apparatus according to the present inventive concept.

FIGS. 5 to 7 are enlarged views illustrating the enlargement of a portion B of FIG. 4.

### MODE FOR INVENTIVE CONCEPT

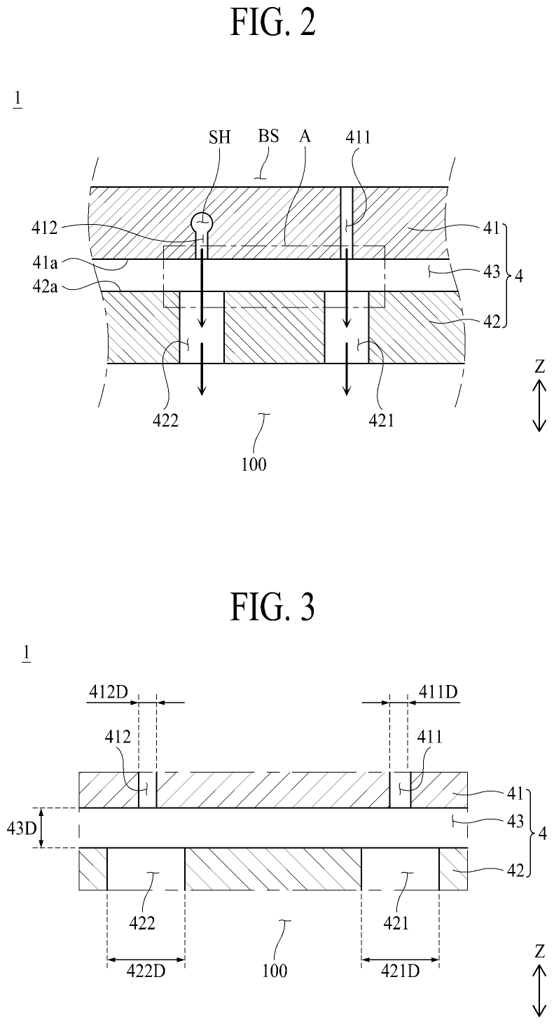

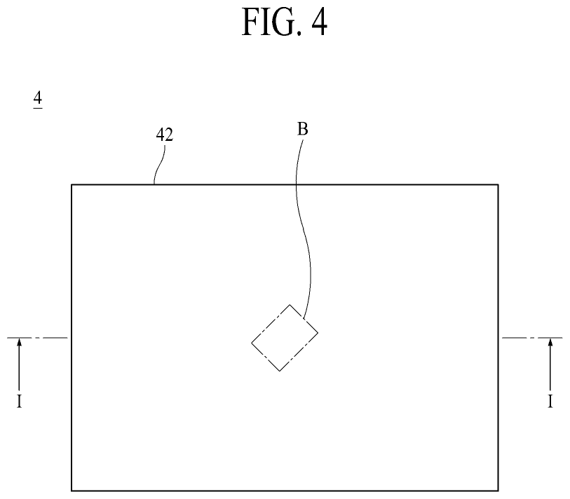

Hereinafter, an embodiment of a substrate processing apparatus according to the present inventive concept will be described in detail with reference to the accompanying drawings. FIG. 2 may be a side cross-sectional view taken along line I-I of FIG. 4. In FIG. 4, openings formed in a lower plate are omitted.

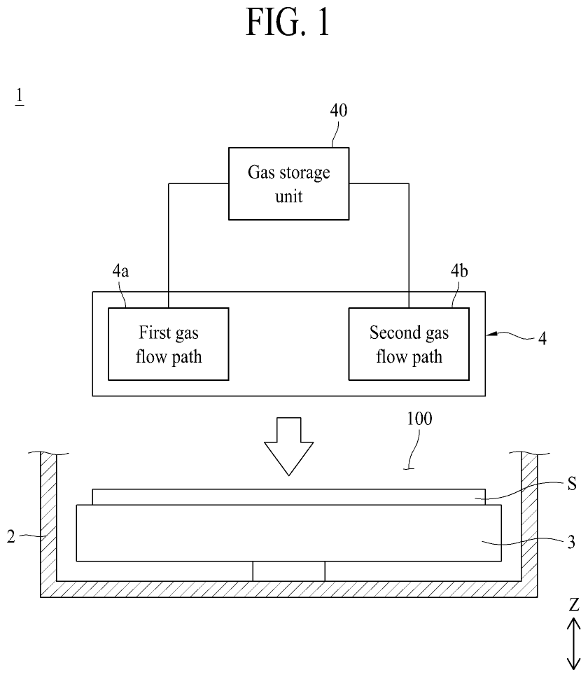

Referring to FIG. 1, a substrate processing apparatus 1 according to the present inventive concept performs a processing process on a substrate S. The substrate S may be a silicon substrate, a glass substrate, a metal substrate, or the like. The substrate processing apparatus 1 according to the present inventive concept may perform a deposition process of depositing a thin film on the substrate S, an etching process of removing a portion of the thin film deposited on the substrate S, etc. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a chamber 2, a substrate supporting unit 3, and a gas injection unit 4.

### <Chamber>

Referring to FIG. 1, the chamber 2 provides a processing space 100. A processing process such as a deposition process and an etching process on the substrate S may be performed in the processing space 100. The processing space 100 may be disposed in the chamber 2. An exhaust port (not shown) which exhausts a gas from the processing space 100 may be coupled to the chamber 2. The substrate supporting unit 3 and the gas injection unit 4 may be disposed in the chamber 2.

### <Substrate Supporting Unit>

Referring to FIG. 1, the substrate supporting unit 3 supports the substrate S. The substrate supporting unit 3 may support one substrate S, or may support a plurality of substrates S. In a case where the plurality of substrates S are supported by the substrate supporting unit 3, the processing process may be performed on the plurality of substrates S at a time. The substrate supporting unit 3 may be coupled to the chamber 2. The substrate supporting unit 3 may be disposed in the chamber 2.

### <Gas Injection Unit>

Referring to FIG. 1, the gas injection unit 4 injects a gas toward the substrate supporting unit 3. The gas injection unit 4 may be disposed in the chamber 2. The gas injection unit 4 may be disposed to be opposite to the substrate supporting unit 3. The gas injection unit 4 may be disposed over the substrate supporting unit 3 with respect to a vertical direction (a Z-axis direction). The vertical direction (the Z-axis direction) is an axis direction parallel to a direction in which the gas injection unit 4 is apart from the substrate supporting unit 3. The processing space 100 may be disposed between the gas injection unit 4 and the substrate supporting unit 3. The gas injection unit 4 may be coupled to a lid (not shown). The lid may be coupled to the chamber 2 to cover an upper portion of the chamber 2. The gas injection unit 4 may be connected to a gas storage unit 40. In this case, the gas injection unit 4 may inject a gas, supplied from the gas storage unit 40, toward the substrate supporting unit 3.

The gas injection unit 4 may include a first gas flow path 4a and a second gas flow path 4b.

The first gas flow path 4a is for injecting a first gas. The first gas flow path 4a may be connected to the gas storage unit 40 at one side thereof through a pipe, a hose, or the like. The other side of the first gas flow path 4a may communicate with the processing space 100. Therefore, the first gas supplied from the gas storage unit 40 may flow along the first gas flow path 4a, and then, may be injected into the processing space 100 through the first gas flow path 4a. The first gas flow path 4a may function as a flow path for enabling the first gas to flow and may function as an injection port for injecting the first gas.

The second gas flow path 4b is for injecting a second gas. The second gas and the first gas may be different gases. For example, one of the first gas and the second gas may be a source gas, and the other of the first gas and the second gas may be a reactant gas. The second gas flow path 4b may be connected to the gas storage unit 40 at one side thereof through a pipe, a hose, or the like. The other side of the second gas flow path 4b may communicate with the processing space 100. Therefore, the second gas supplied from the gas storage unit 40 may flow along the second gas flow path 4b, and then, may be injected into the processing space 100 through the second gas flow path 4b. The second gas flow path 4b may function as a flow path for enabling the second gas to flow and may function as an injection port for injecting the second gas.

The second gas flow path 4b and the first gas flow path 4a may be disposed to be spatially apart from each other. Therefore, the second gas supplied from the gas storage unit 40 to the second gas flow path 4b may be injected into the processing space 100 without passing through the first gas flow path 4a. The first gas supplied from the gas storage unit 40 to the first gas flow path 4a may be injected into the processing space 100 without passing through the second gas flow path 4b.

Referring to FIGS. 1 to 3, the gas injection unit 4 may include an upper plate 41 and a lower plate 42.

The upper plate 41 is disposed over the lower plate 42. The upper plate 41 and the lower plate 42 may be disposed apart from each other in the vertical direction (the Z-axis direction). A separation space 43 may be disposed between the upper plate 41 and the lower plate 42. The upper plate 41 and the lower plate 42 may be disposed not to be electrically connected to each other through the separation space 43. Although not shown, an insulation member which electrically insulates the upper plate 41 from the lower plate 42 may be disposed in the separation space 43. A bottom surface 41a (illustrated in FIG. 2) of the upper plate 41 may be formed to be flat.

The upper plate 41 may include a first injection hole 411 and a second injection hole 412.

The first injection hole 411 is for providing the first gas. The first injection hole 411 may provide the first gas in a downward direction toward the lower plate 42 from a portion on the lower plate 42. In this case, the first injection hole 411 may inject the first gas in the downward direction, and thus, may provide the first gas. The first injection hole 411 may be formed to pass through the upper plate 41. The first injection hole 411 may be connected to the gas storage unit 40 through a buffer space BS (not shown in FIG. 2). The buffer space BS may be a space which is disposed on the upper plate 41. The buffer space BS may be disposed between the lid and the upper plate 41 with respect to the vertical direction (the Z-axis direction). The first injection hole 411 and the buffer space BS may be included in the first gas flow path 4a. The first injection hole 411 may provide the first gas, flowing in from the outside of the chamber 2, toward the lower plate 42. The upper plate 41 may include the first injection hole 411 which are provided in plurality. The first injection holes 411 may be disposed apart from one another.

The second injection hole 412 is for providing the second gas. The second injection hole 412 may provide the second gas in the downward direction. In this case, the second injection hole 412 may inject the second gas in the downward direction, and thus, may provide the second gas. The second injection hole 412 may be connected to the gas storage unit 40 through a supply hole SH (illustrated in FIG. 2). The supply hole SH may be formed in the upper plate 41. The supply hole SH may be implemented by processing an inner portion of the upper plate 41 with a gun drill. The second injection hole 412 and the supply hole SH may be included in the second gas flow path 4b. The second injection hole 412 may provide the second gas, flowing in from the outside of the chamber 2, toward the lower plate 42. The upper plate 41 may include the second injection hole 412 which are provided in plurality. The second injection holes 412 may be disposed apart from one another. In this case, the plurality of second injection holes 412 may be connected to the supply hole SH. The second injection holes 412 may be apart from one another and may be connected to different portions of the supply hole SH. The supply hole SH may be provided in plurality in the upper plate 41. The plurality of second injection holes 412 may be respectively connected to the supply holes SH.

The lower plate 42 is disposed over the substrate supporting unit 3. The lower plate 42 may be disposed between the substrate supporting unit 3 and the upper plate 41 with respect to the vertical direction (the Z-axis direction). The lower plate 42 may be disposed so that a top surface 42a thereof faces the bottom surface 41a of the upper plate 41. The separation space 43 may be disposed between the top surface 42a of the lower plate 42 and the bottom surface 41a of the upper plate 41. In FIG. 4, it is illustrated that the lower plate 42 is provided in a tetragonal shape, but the present inventive concept is not limited thereto and the lower plate 42 may be provided in a different shape such as a circular shape. The lower plate 42 and the upper plate 41 may be provided in an approximately matching shape.

The lower plate 42 may include a first opening 421 and a second opening 422.

The first opening 421 is for allowing the first gas to pass through the first opening 421. The first opening 421 may be formed to pass through the lower plate 42. The first opening 421 may be disposed under the first injection hole 411. Therefore, the first gas provided from the first injection hole 411 may pass through the first opening 421 and may be injected toward the substrate supporting unit 3. The first opening 421 and the first injection hole 411 may be included in the first gas flow path 4a. In this case, the first gas provided from the first injection hole 411 may flow into the first opening 421 via the separation space 43, may pass through the first opening 421, and may be injected toward the substrate supporting unit 3.

The second opening 422 is for allowing the second gas to pass through the second opening 422. The second opening 422 may be formed to pass through the lower plate 42. The second opening 422 may be disposed apart from the first opening 421. The second opening 422 may be disposed under the second injection hole 412. Therefore, the second gas provided from the second injection hole 412 may pass through the second opening 422 and may be injected toward the substrate supporting unit 3. The second opening 422 and the second injection hole 412 may be included in the second gas flow path 4b. In this case, the second gas provided from the second injection hole 412 may flow into the second opening 422 via the separation space 43, may pass through the second opening 422, and may be injected toward the substrate supporting unit 3.

As described above, the substrate processing apparatus 1 according to the present inventive concept is implemented to inject the first gas into the processing space 100 by using the first opening 421 and the first injection hole 411 and inject the second gas into the processing space 100 by using the second opening 422 and the second injection hole 412. Therefore, the substrate processing apparatus 1 according to the present inventive concept may decrease the mixed amount of the first gas and the second gas before the first gas and the second gas are injected into the processing space 100. Therefore, the substrate processing apparatus 1 according to the present inventive concept may reduce particles which occur as the first gas and the second gas react before the first gas and the second gas are injected into the processing space 100. Accordingly, the substrate processing apparatus 1 according to the present inventive concept may enhance the quality of a substrate S on which the processing process is completed, and moreover, may increase a period of a cleaning operation which should be performed on the gas injection unit 4 so as to remove particles, thereby contributing to reduce the process cost.

Referring to FIGS. 1 to 3, the lower plate 42 may be connected to a radio frequency (RF) power source so that the first gas is activated and the second gas is activated. In this case, when the upper plate 41 is grounded and an RF power is applied to the lower plate 42, plasma may be generated. Accordingly, by using plasma, the lower plate 42 may activate the first gas and may activate the second gas.

Therefore, the substrate processing apparatus 1 according to the present inventive concept may be implemented so that the activated first gas and the activated second gas are mixed and react in the processing space 100, and thus, the film quality of a thin film deposited on the substrate S may be enhanced. Also, in the substrate processing apparatus 1 according to the present inventive concept, the bottom surface 41a of the upper plate 41 may be formed to be flat. Accordingly, comparing with a comparative example where a protrusion electrode protruding from the bottom surface 41a of the upper plate 41 is provided, the substrate processing apparatus 1 according to the present inventive concept may remove power consumption concentrating on the protrusion electrode in the comparative example, and thus, may reduce the amount of power consumption compared to the comparative example, thereby contributing to reduce the process cost

The lower plate 42 may be implemented so that plasma is generated in each of the first opening 421 and the second opening 422. Therefore, the first gas may be activated by plasma which is generated in the first opening 421 in a process of passing through the first opening 421, and then, may be injected into the processing space 100. Also, the second gas may be activated by plasma which is generated in the second opening 422 in a process of passing through the second opening 422, and then, may be injected into the processing space 100.

Referring to FIGS. 1 to 3, in the substrate processing apparatus 1 according to the present inventive concept, an interval 43D (illustrated in FIG. 3) (hereinafter referred to as a ‘separation interval 43D’) by which the upper plate 41 and the lower plate 42 are apart from each other may be implemented to be less than each of a diameter 421D (illustrated in FIG. 3) of the first opening 421 and a diameter 422D (illustrated in FIG. 3) of the second opening 422. Therefore, the substrate processing apparatus 1 according to the present inventive concept may be implemented to prevent plasma from being generated between the upper plate 41 and the lower plate 42 and simultaneously allow plasma to be generated in each of the first opening 421 and the second opening 422. Accordingly, the substrate processing apparatus 1 according to the present inventive concept may be implemented so that the first gas is activated in the first opening 421 and the second gas is activated in the second opening 422.

In this case, the separation interval 43D may be set to a length which prevents plasma from being generated between the upper plate 41 and the lower plate 42. Also, the separation interval 43D may be set to a length for electrically insulating the upper plate 41 from the lower plate 42. For example, the separation interval 43D may be set to 1.5 mm or more and less than 2 mm. When the separation interval 43D is less than 1.5 mm, the upper plate 41 may not be electrically insulated from the lower plate 42. When the separation interval 43D is 2 mm or more, plasma may be generated between the upper plate 41 and the lower plate 42. Based thereon, the substrate processing apparatus 1 according to the present inventive concept may be implemented so that the separation interval 43D is set to 1.5 mm or more and less than 2 mm, and thus, the upper plate 41 is electrically insulated from the lower plate 42 and plasma is prevented from being generated between the upper plate 41 and the lower plate 42.

Referring to FIGS. 1 to 3, the first opening 421 may be formed to have the diameter 421D which is greater than the separation interval 43D. In this case, the diameter 421D of the first opening 421 may be set to a length which allows plasma to be generated in the first opening 421. For example, the diameter 421D of the first opening 421 may be set to a length of 2 mm to 5 mm. The first opening 421 may be formed to have the diameter 421D which is greater than the first injection hole 411. In this case, a diameter 411D (illustrated in FIG. 3) of the first injection hole 411 may be set to be less than the diameter 421D of the first opening 421. Accordingly, the substrate processing apparatus 1 according to the present inventive concept may be implemented so that plasma is intensively generated in the first opening 421, and thus, may be implemented so that the first gas is intensively activated in the first opening 421 and is injected into the processing space 100.

Referring to FIGS. 1 to 3, the second opening 422 may be formed to have the diameter 422D which is greater than the separation interval 43D. In this case, the diameter 422D of the second opening 422 may be set to a length which allows plasma to be generated in the second opening 422. For example, the diameter 422D of the second opening 422 may be set to a length of 2 mm to 5 mm. The second opening 422 may be formed to have the diameter 422D which is greater than the second injection hole 412. In this case, a diameter 412D (illustrated in FIG. 3) of the second injection hole 412 may be set to be less than the diameter 422D of the second opening 422. Accordingly, the substrate processing apparatus 1 according to the present inventive concept may be implemented so that plasma is intensively generated in the second opening 422, and thus, may be implemented so that the second gas is intensively activated in the second opening 422 and is injected into the processing space 100. Furthermore, the diameter 422D of the second opening 422 and the diameter 421D of the first opening 421 may be set to be equal.

Referring to FIGS. 1 to 7, the lower plate 42 may include the first opening 421 and the second opening 422 which are each provided in plurality.

The first openings 421 may be disposed apart from one another. The number of first openings 421 included in the lower plate 42 may be equal to the number of first injection holes 411 included in the upper plate 41. The first openings 421 may be respectively disposed under the first injection holes 411. In this case, the first openings 421 and the first injection holes 411 may be arranged in a one-to-one correspondence relationship.

The second openings 422 may be disposed apart from one another. The number of second openings 422 included in the lower plate 42 may be equal to the number of second injection holes 412 included in the upper plate 41. The second openings 422 may be respectively disposed under the second injection holes 412. In this case, the second openings 422 and the second injection holes 412 may be arranged in a one-to-one correspondence relationship.

Here, the substrate processing apparatus 1 according to the present inventive concept may be implemented so that the first openings 421 and the second openings 422 are arranged as the following arrangement type. In this case, the first injection holes 411 and the second injection holes 412 may be respectively disposed over the first opening 421 and the second opening 422, and thus, may be arranged as the same arrangement type as an arrangement type between the first opening 421 and the second opening 422. Therefore, the descriptions of the arrangement type between the first openings 421 and the second openings 422 are applied to descriptions of an arrangement type between the first injection holes 411 and the second injection holes 412. Furthermore, a center of each of the second openings 422 and a center of each of the second injection holes 412 may be arranged on the same line with respect to the vertical direction (the Z-axis direction).

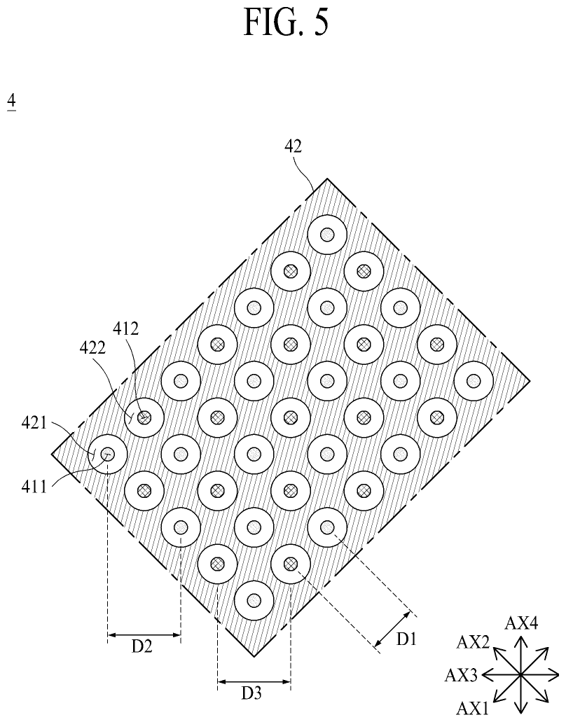

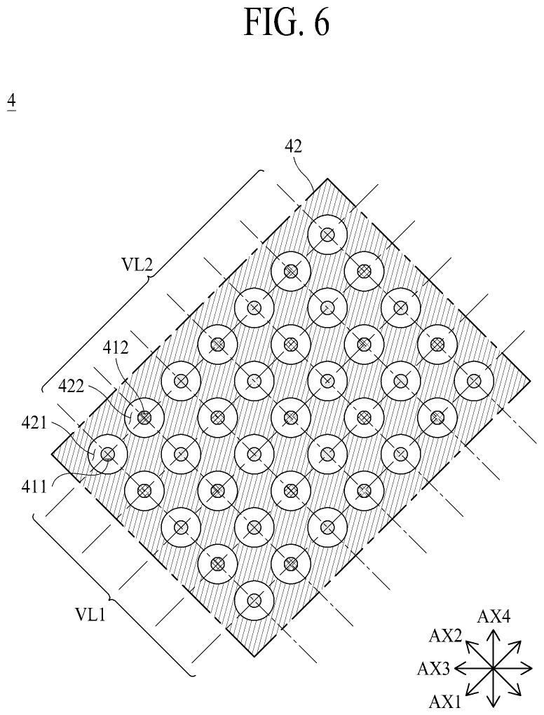

First, in FIGS. 5 and 6, the lower plate 42 is hatched for differentiating the first openings 421, the second openings 422, and the lower plate 42, and the first openings 421 and the second openings 422 are not hatched. Also, the first injection holes 411 and the second injection holes 412 are hatched in different shapes so as to differentiate the first injection holes 411 and the second injection holes 412.

Next, as illustrated in FIG. 5, an interval D1 [hereinafter referred to as a ‘mixture interval D1’] by which the first opening 421 and the second opening 422 disposed adjacent to each other are apart from each other may be implemented to be less than an interval D2 [hereinafter referred to as a ‘first opening interval D2’] by which the first openings 421 are apart from each other and an interval D3 [hereinafter referred to as a ‘second opening interval D3’] by which the second openings 422 are apart from each other. That is, the mixture interval D1 may be implemented to be less than each of the first opening interval D2 and the second opening interval D3.

Therefore, the substrate processing apparatus 1 according to the present inventive concept may decrease a distance by which an injection position of the first gas and an injection position of the second gas are apart from each other toward the processing space 100 from the lower plate 42. Accordingly, the substrate processing apparatus 1 according to the present inventive concept may enhance reactivity between the first gas and the second gas in the processing space 100, and thus, may more enhance the quality of a substrate S on which the processing process is completed.

Furthermore, the mixture interval D1 may denote a rectilinear distance which joins the center of the first opening 421 and the center of the second opening 422 as short as possible, in the first opening 421 and the second opening 422 disposed adjacent to each other. The first opening interval D2 may denote a rectilinear distance which joins centers of the first openings 421 as short as possible, in two first openings 421 disposed adjacent to each other. The second opening interval D3 may denote a rectilinear distance which joins centers of the second openings 422 as short as possible, in two second openings 422 disposed adjacent to each other.

Next, as illustrated in FIG. 6, the first opening 421 and the second opening 422 may be alternately arranged in plurality along each of a plurality of first virtual lines VL1 in the lower plate 42. The first virtual lines VL1 are virtual lines parallel with a first-axis direction (an AX1-axis direction). The first virtual lines VL1 may be arranged apart from one another in a second-axis direction (an AX2-axis direction) vertical to the first-axis direction (the AX1-axis direction).

As described above, the first opening 421 and the second opening 422 may be alternately arranged in plurality along each of the first virtual lines VL1 in the order of the first opening 421, the second opening 422, the first opening 421, and the second opening 422, and thus, the substrate processing apparatus 1 according to the present inventive concept may decrease a distance by which an injection position of the first gas and an injection position of the second gas are apart from each other along each of the first virtual lines VL1. Accordingly, the substrate processing apparatus 1 according to the present inventive concept may enhance reactivity between the first gas and the second gas in the processing space 100 with respect to each of the first virtual lines VL1. Therefore, the substrate processing apparatus 1 according to the present inventive concept may increase the uniformity of a processing process on the substrate S with respect to the first-axis direction (the AX1-axis direction).

Next, as illustrated in FIG. 6, the first opening 421 and the second opening 422 may be alternately arranged in plurality along each of a plurality of second virtual lines VL2 in the lower plate 42. The second virtual lines VL2 are virtual lines parallel with the second-axis direction (the AX2-axis direction). The second virtual lines VL2 may be arranged apart from one another in the first-axis direction (the AX1-axis direction).

As described above, the first opening 421 and the second opening 422 may be alternately arranged in plurality along each of the second virtual lines VL2 in the order of the first opening 421, the second opening 422, the first opening 421, and the second opening 422, and thus, the substrate processing apparatus 1 according to the present inventive concept may decrease a distance by which an injection position of the first gas and an injection position of the second gas are apart from each other along each of the second virtual lines VL2. Accordingly, the substrate processing apparatus 1 according to the present inventive concept may enhance reactivity between the first gas and the second gas with respect to each of the second virtual lines VL2. Therefore, the substrate processing apparatus 1 according to the present inventive concept may increase the uniformity of a processing process on the substrate S with respect to the second-axis direction (the AX2-axis direction).

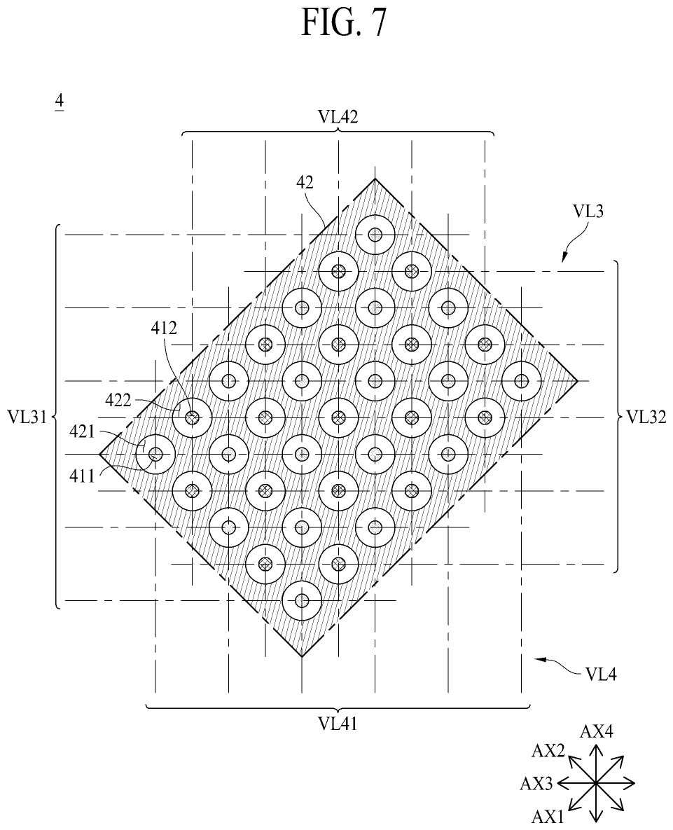

Next, as illustrated in FIG. 7, the first opening 421 may be arranged in plurality along each of odd-numbered third virtual lines VL31 of a plurality of third virtual lines VL3 in the lower plate 42. The second opening 422 may be arranged in plurality along each of even-numbered third virtual lines VL32 of the plurality of third virtual lines VL3 in the lower plate 42. The third virtual lines VL3 are virtual lines parallel with a third-axis direction (an AX3-axis direction). The third-axis direction (the AX3-axis direction) is an axis direction arranged between the first-axis direction (the AX1-axis direction) and the second-axis direction (the AX2-axis direction). The third-axis direction (the AX3-axis direction) may be an axis direction which is apart from the first-axis direction (the AX1-axis direction) and the second-axis direction (the AX2-axis direction) at a 45-degree angle. The third virtual lines VL3 may be arranged apart from one another in a fourth-axis direction (an AX4-axis direction) vertical to the third-axis direction (the AX3-axis direction).

As described above, the first opening 421 may be arranged in plurality along each of the odd-numbered third virtual lines VL31 and the second opening 422 may be arranged in plurality along each of the even-numbered third virtual lines VL32, and thus, in the substrate processing apparatus 1 according to the present inventive concept, a line consisting of the first openings 421 and a line consisting of the second openings 422 may be alternately arranged with respect to the fourth-axis direction (the AX4-axis direction). Accordingly, the substrate processing apparatus 1 according to the present inventive concept may enhance reactivity between the first gas and the second gas with respect to the fourth-axis direction (the AX4-axis direction), and thus, may increase the uniformity of a processing process on the substrate S with respect to the fourth-axis direction (the AX4-axis direction).

Furthermore, the first openings 421 arranged along the odd-numbered third virtual lines VL31 and the second openings 422 arranged along the even-numbered third virtual lines VL32 may be arranged to be staggered with respect to the third-axis direction (the AX3-axis direction). Accordingly, the substrate processing apparatus 1 according to the present inventive concept may more decrease a distance by which the first opening 421 and the second opening 422 are apart from each other.

Next, as illustrated in FIG. 7, the first opening 421 may be arranged in plurality along each of odd-numbered fourth virtual lines VL41 of a plurality of fourth virtual lines VL4 in the lower plate 42. The second opening 422 may be arranged in plurality along each of even-numbered fourth virtual lines VL42 of the plurality of fourth virtual lines VL4 in the lower plate 42. The fourth virtual lines VL4 are virtual lines parallel with the fourth-axis direction (the AX4-axis direction). The fourth virtual lines VL4 may be arranged apart from one another in the third-axis direction (the AX3-axis direction).

As described above, the first opening 421 may be arranged in plurality along each of the odd-numbered fourth virtual lines VL41 and the second opening 422 may be arranged in plurality along each of the even-numbered fourth virtual lines VL42, and thus, in the substrate processing apparatus 1 according to the present inventive concept, a line consisting of the first openings 421 and a line consisting of the second openings 422 may be alternately arranged with respect to the third-axis direction (the AX3-axis direction). Accordingly, the substrate processing apparatus 1 according to the present inventive concept may enhance reactivity between the first gas and the second gas with respect to the third-axis direction (the AX3-axis direction), and thus, may increase the uniformity of a processing process on the substrate S with respect to the third-axis direction (the AX3-axis direction).

Furthermore, the first openings 421 arranged along the odd-numbered fourth virtual lines VL41 and the second openings 422 arranged along the even-numbered fourth virtual lines VL42 may be arranged to be staggered with respect to the third-axis direction (the AX3-axis direction). Accordingly, the substrate processing apparatus 1 according to the present inventive concept may more decrease a distance by which the first opening 421 and the second opening 422 are apart from each other.

As described above, in describing an arrangement relationship with respect to one first opening 421 of the first openings 421 formed in the lower plate 42 in the substrate processing apparatus 1 according to the present inventive concept, the first opening 421 may be disposed adjacent to the second opening 422 with respect to each of the first-axis direction (the AX1-axis direction) and the second-axis direction (the AX2-axis direction) and may be disposed adjacent to the first opening 421 with respect to each of the third-axis direction (the AX3-axis direction) and the fourth-axis direction (the AX4-axis direction). Also, in describing an arrangement relationship with respect to one second opening 422 of the second openings 422 formed in the lower plate 42, the second opening 422 may be disposed adjacent to the first opening 421 with respect to each of the first-axis direction (the AX1-axis direction) and the second-axis direction (the AX2-axis direction) and may be disposed adjacent to the second opening 422 with respect to each of the third-axis direction (the AX3-axis direction) and the fourth-axis direction (the AX4-axis direction). To provide a summary on the above description, the substrate processing apparatus 1 according to the present inventive concept may be implemented so that mixture arrangement where the first opening 421 and the second opening 422 are mixed is formed with respect to the first-axis direction (the AX1-axis direction) and the second-axis direction (the AX2-axis direction), and the same arrangement consisting of only the first opening 421 or only the second opening 422 is formed.

Likewise, in describing an arrangement relationship with respect to one first injection hole 411 of the first injection holes 411 formed in the upper plate 41, the first injection hole 411 may be disposed adjacent to the second injection hole 412 with respect to each of the first-axis direction (the AX1-axis direction) and the second-axis direction (the AX2-axis direction) and may be disposed adjacent to the first injection hole 411 with respect to each of the third-axis direction (the AX3-axis direction) and the fourth-axis direction (the AX4-axis direction). Also, in describing an arrangement relationship with respect to one second injection hole 412 of the second injection holes 412 formed in the upper plate 41, the second injection hole 412 may be disposed adjacent to the first injection hole 411 with respect to each of the first-axis direction (the AX1-axis direction) and the second-axis direction (the AX2-axis direction) and may be disposed adjacent to the second injection hole 412 with respect to each of the third-axis direction (the AX3-axis direction) and the fourth-axis direction (the AX4-axis direction). To provide a summary on the above description, the substrate processing apparatus 1 according to the present inventive concept may be implemented so that mixture arrangement where the first injection hole 411 and the second injection hole 412 are mixed is formed with respect to the first-axis direction (the AX1-axis direction) and the second-axis direction (the AX2-axis direction), and the same arrangement consisting of only the first injection hole 411 or only the second injection hole 412 is formed.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A substrate processing apparatus comprising:
a chamber;
a substrate supporting unit supporting at least one substrate in the chamber;
a lower plate disposed over the substrate supporting unit; and
an upper plate disposed over the lower plate,
wherein the upper plate comprises a first injection hole providing a first gas and a second injection hole providing a second gas, and
the lower plate comprises a first opening disposed under the first injection hole to allow the first gas provided from the first injection hole to pass through the first opening, and a second opening disposed under the second injection hole to allow the second gas provided from the second injection hole to pass through the second opening.

2. The substrate processing apparatus of claim 1, wherein
the upper plate is grounded, and
the lower plate is connected to a radio frequency (RF) power source so that the first gas is activated and the second gas is activated.

3. The substrate processing apparatus of claim 1, wherein an interval by which the upper plate and the lower plate are apart from each other is less than each of a diameter of the first opening and a diameter of the second opening.

4. The substrate processing apparatus of claim 1, wherein
a diameter of the first opening is set to a length which allows plasma to be generated in the first opening,
a diameter of the second opening is set to a length which allows plasma to be generated in the second opening, and
the interval by which the upper plate and the lower plate are apart from each other is set to a length which prevents plasma from being generated between the upper plate and the lower plate.

5. The substrate processing apparatus of claim 1, wherein
the first opening is formed to have a diameter which is greater than the first injection hole, and
the second opening is formed to have a diameter which is greater than the second injection hole.

6. The substrate processing apparatus of claim 1, wherein
the first opening and the second opening are alternately arranged in plurality along each of a plurality of first virtual lines in the lower plate, the first virtual lines are parallel with a first-axis direction, and
the first virtual lines are apart from one another in a second-axis direction vertical to the first-axis direction.

7. The substrate processing apparatus of claim 6, wherein
the first opening and the second opening are alternately arranged in plurality along each of a plurality of second virtual lines in the lower plate, the second virtual lines are parallel with the second-axis direction, and
the second virtual lines are apart from one another in the first-axis direction.

8. The substrate processing apparatus of claim 6 or 7, wherein
the first opening is arranged in plurality along each of odd-numbered third virtual lines of a plurality of third virtual lines in the lower plate, the third virtual lines are parallel with a third-axis direction between the first-axis direction and the second-axis direction,
the second opening is arranged in plurality along each of even-numbered third virtual lines in the lower plate, and
the third virtual lines are apart from one another in a fourth-axis direction vertical to the third-axis direction.

9. The substrate processing apparatus of claim 8, wherein the first openings arranged along the odd-numbered third virtual lines and the second openings arranged along the even-numbered third virtual lines are arranged to be staggered with respect to the third-axis direction.

10. The substrate processing apparatus of claim 8, wherein
the first opening is arranged in plurality along each of odd-numbered fourth virtual lines of a plurality of fourth virtual lines in the lower plate, the fourth virtual lines are parallel with the fourth-axis direction,
the second opening is arranged in plurality along each of even-numbered fourth virtual lines in the lower plate, and
the fourth virtual lines are apart from one another in the third-axis direction.

11. The substrate processing apparatus of claim 1, wherein
the lower plate comprises the first opening and the second opening which are each provided in plurality,
an interval, by which the first opening and the second opening disposed adjacent to each other are apart from each other, is less than an interval by which the first openings are apart from each other, and
an interval, by which the first opening and the second opening disposed adjacent to each other are apart from each other, is less than an interval by which the second openings are apart from each other.

12. The substrate processing apparatus of claim 1, wherein
one of the first gas and the second gas is a source gas, and
the other of the first gas and the second gas is a reactant gas.

13. The substrate processing apparatus of claim 2, wherein an interval by which the upper plate and the lower plate are apart from each other is less than each of a diameter of the first opening and a diameter of the second opening.

14. The substrate processing apparatus of claim 2, wherein
a diameter of the first opening is set to a length which allows plasma to be generated in the first opening,
a diameter of the second opening is set to a length which allows plasma to be generated in the second opening, and
the interval by which the upper plate and the lower plate are apart from each other is set to a length which prevents plasma from being generated between the upper plate and the lower plate.

15. The substrate processing apparatus of claim 7, wherein
the first opening is arranged in plurality along each of odd-numbered third virtual lines of a plurality of third virtual lines in the lower plate, the third virtual lines are parallel with a third-axis direction between the first-axis direction and the second-axis direction,
the second opening is arranged in plurality along each of even-numbered third virtual lines in the lower plate, and
the third virtual lines are apart from one another in a fourth-axis direction vertical to the third-axis direction.

16. The substrate processing apparatus of claim 15, wherein the first openings arranged along the odd-numbered third virtual lines and the second openings arranged along the even-numbered third virtual lines are arranged to be staggered with respect to the third-axis direction.

17. The substrate processing apparatus of claim 15, wherein
the first opening is arranged in plurality along each of odd-numbered fourth virtual lines of a plurality of fourth virtual lines in the lower plate, the fourth virtual lines are parallel with the fourth-axis direction,
the second opening is arranged in plurality along each of even-numbered fourth virtual lines in the lower plate, and
the fourth virtual lines are apart from one another in the third-axis direction.
